(19) United States
(12) Patent Application Publication
(10) Pub. No.: US 2026/0341329 A1
(43) Pub. Date: Oct. 29, 2026

(54) APPARATUSES SYSTEMS AND METHODS FOR OVERLAPPING COMMANDS IN A MEMORY DEVICE

(71) Applicant: Micron Technology, Inc., Boise, ID (US)

(72) Inventors: Yang Lu, Boise, ID (US); Joseph Riad, College Station, TX (US)

(73) Assignee: Micron Technology, Inc., Boise, ID (US)

(21) Appl. No.: 19/187,051

(22) Filed: Apr. 23, 2025

(51) Int. Cl. G11C 11/406; G11C 11/408

(52) U.S. Cl. CPC G11C 11/40603; G11C 11/40618; G11C 11/4087

(57) ABSTRACT

A memory device includes a row address bus coupled to the memory banks. The row address bus may carry addresses with refresh address flags. When a bank receives an activation signal it will latch an address with an inactive refresh address flag if the bank is receiving an inactive refresh signal or an address with an active refresh flag if the bank is receiving an active refresh signal. The memory device may include a dynamic refresh timer circuit with a number of array timers. When a refresh command is received, a currently unused one of the array timers is assigned to the refresh operation(s) responsive to that command. The assigned array timer provides the activation signal to the bank(s) where the refresh is being performed.

### BACKGROUND

This disclosure relates generally to semiconductor devices, and more specifically to semiconductor memory devices. In particular, the disclosure relates to volatile memory, such as dynamic random access memory (DRAM). Information is stored in the memory on memory cells as a physical signal such as a charge on a capacitive element. During an access operation, an access command may be received on a command and address bus along with address information which specifies which memory cells should be accessed.

Information may decay over time in the memory cells. For example, the memory cells may discharge over time. In order to preserve the integrity of the stored information, the memory cells may be refreshed, for example to restore an initial charge level associated with the stored information. The memory receives a refresh command on said command and address bus which instructs it to perform one or more refresh operations. However, the refresh command occupies the command and address bus which may be unavailable to accept access commands due to bandwidth limits. It may be desirable to find ways to reduce the amount of time the command and address bus is unavailable for access operations while still making sure that refresh operations are occurring.

### BRIEF DESCRIPTION OF THE DRAWINGS

FIG. 1 is a block diagram of a semiconductor device according to some embodiments of the disclosure.

FIG. 2 is block diagram of bank operation logic according to some embodiments of the present disclosure.

FIG. 3 is a block diagram of an example layout of a memory device according to some embodiments of the present disclosure.

FIG. 4 is a block diagram of row address capture logic for a bank according to some example embodiments of the current disclosure.

FIGS. 5A-5C are timing diagrams of access operations in an example memory device according to some embodiments of the present disclosure.

FIG. 6 is a flow chart of a method of sharing a row address bus for access operations and refresh operations according to some embodiments of the present disclosure.

FIG. 7 is a block diagram of a dynamic refresh timer logic circuit according to some embodiments of the present disclosure.

FIG. 8 is a timing diagram of overlapping refresh operations using a dynamic refresh timer circuit according to some embodiments of the current disclosure.

FIG. 9 is a flow chart of a method of dynamically assigning array timers for refresh operations according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present apparatuses, systems, methods, and combinations thereof, reference is made to the accompanying drawings. The drawings are shown by way of illustration of specific example embodiments of how the described apparatuses, systems, methods, or combinations thereof may be practiced. These embodiments are described in sufficient detail to enable those skilled in the art to practice presently disclosed apparatuses, systems, methods, and combinations thereof, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device includes a memory array. The memory array includes a number of memory cells. The memory cells are at the intersection of bit lines and word lines. The bit lines and word lines may be considered as columns and rows respectively in a logical organization of the array. The memory array is also divided into multiple banks. Accordingly, a row address may specify one or more word lines, a column address may specify one or more bit lines, and a bank address may specify one or more banks.

During an access operation such as a read or write operation, the memory receives access commands and a bank, row, and column address on a command and address bus. The memory receives a row activation command and activates the word line specified by the row address in the bank specified by the bank address. While active, data may be read or written along the bit lines specified by the column address responsive to column commands such as read or write commands. The bit lines are coupled to sense amplifiers. The sense amplifiers sense a voltage on the bit line from the memory cells along the active word line and amplify it into a signal in a read operation or drive a voltage to the memory cell along the active word line in a write operation.

During refresh operations, one or more word lines are activated, and the sense amplifiers restore the charge in the memory cell without the bit lines being coupled outside the memory array. Refresh operations may be performed responsive to refresh commands, such as all-bank refresh REFab, dual-bank refresh REFdb, or other refresh commands. Refresh operations may also be performed as part of other operations or commands, such as a linked activation command ACTL.

Some commands may cause multiple operations to occur. For example, a linked activation command ACTL may send an access command to a first bank and allow the memory to perform a refresh operation on a second bank. A dual bank refresh command REFdb may cause two banks to have refresh operations performed on them sequentially. It may be useful to allow such commands to overlap, for example such that while the second refresh operation is happening (e.g., from an ACTL or REFdb command) a next command may be received. Some patterns of commands may cause multiple overlapping refresh operations. For example, if a refresh command is received after an ACTL command, or if multiple REFdb commands are received in a row.

The present disclosure is drawn to apparatuses, systems, and methods for overlapping commands in a memory device. In at least some embodiments, the memory device includes a common refresh address generator which is shared by multiple banks. Row addresses along the row address bus of the memory include one or more additional bits which act as a refresh address flag. When the row address is for a refresh operation, the refresh address flag is active (e.g., a flag bit is in a first state) and when the row address is not for a refresh operation, the refresh address flag is inactive (e.g., the flag bit is in a second state). If a bank receives an activation signal but an inactive refresh signal, indicating an access operation in that bank, it will latch an address off the address bus if the address has an inactive refresh address flag. If a bank receives an activation signal and an active refresh signal, indicating a refresh operation in that bank, it will latch an address off the address bus if the address has an active refresh address flag. In this way, there may be a common refresh address generator and the refresh addresses and row addresses may be sent along a common row address bus even when activation signals for different banks may be active at a same time. This may streamline operations and help eliminate the need to take up space for bank specific refresh address generators in the bank logic.

The memory device may use the common refresh address generator and shared row address bus to facilitate overlapping commands. For example, when the device receives a linked activation command, it first sends an activation command to a first bank and sends a row address associated with the activation command along the row address bus with an inactive refresh address flag, it then generates a refresh address with an active refresh address flag and sends that along the row address bus after the row address and sends an activation signal and a refresh signal to the second bank. The first bank will latch the row address off the bus and the second bank will latch the refresh address off the bus. The first bank will not latch the second address even though the activation signal may be active for both banks when the second address is provided along the bus.

In at least some embodiments, the memory device includes a dynamic refresh timer circuit. The dynamic refresh timer circuit manages the activation signal(s) to bank(s) which are being refreshed. The dynamic refresh timer circuit includes queue logic and multiple array timers. When a refresh command is received (either an explicit refresh command or a command like ACTL that causes a refresh operation), the queue logic checks the array timers and activates a currently unused one of the timers to begin providing activation signals responsive to the refresh command. The array timer provides an activation signal for a period of time based on the duration of the refresh operation. Once done, the array timer is inactivated and can be reused. In this way, array timers can be activated as needed and reallocated to a new refresh command once they are no longer in use. The number of array timers may be based on a maximum number of overlapping refresh operations that the memory device can support.

In an example operation, the memory device may receive a sequence of refresh commands, such as REFdb commands. In some situations, the REFdb command causes a first refresh operation in a first bank and a second refresh operation in a second bank. A next refresh command may be received while one of the refresh operations from the previous refresh command is still occurring. When the first command is received, the dynamic refresh timer circuit assigns a first array timer to generate the sequence of activation signals for the first refresh command, and if a second overlapping refresh command is received, the queue logic will determine that the first array timer is in use and use a second array timer, and so forth.

In at least some embodiments, a memory device may use both a common refresh address generator and row addresses with refresh address flags and a dynamic refresh timer circuit.

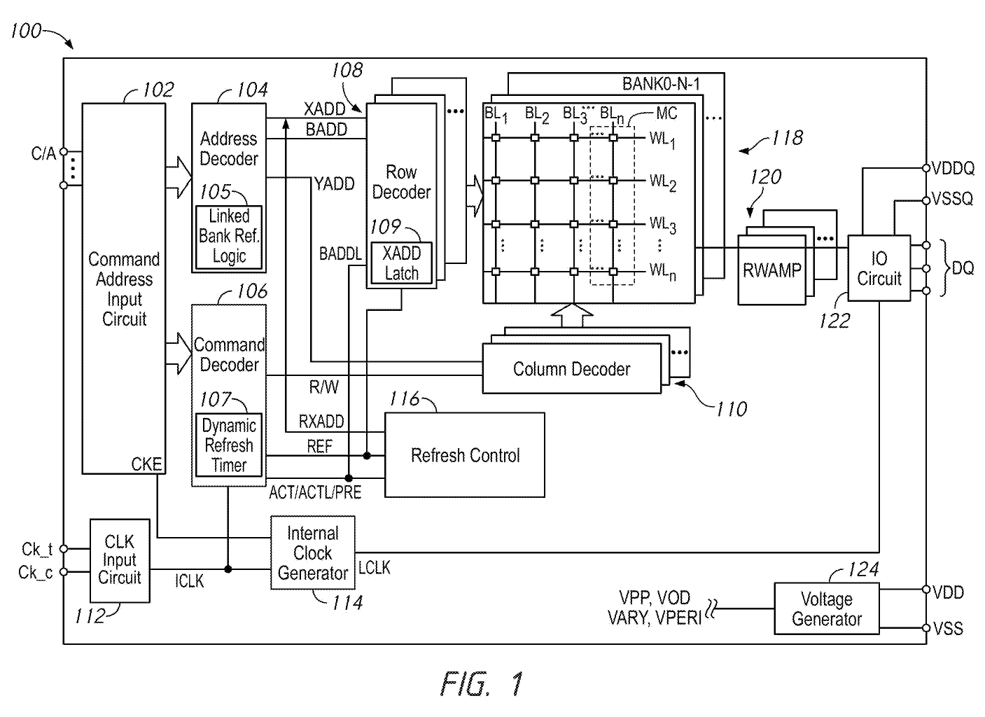

FIG. 1 is a block diagram of a semiconductor device according to some embodiments of the disclosure. The semiconductor device 100 may be a semiconductor memory device, such as a DRAM device integrated on a single semiconductor chip. In some embodiments, the semiconductor device 100 may represent one of a number of memory devices packaged together, such as on a module. In some embodiments, the semiconductor device 100 may represent a stand-alone memory device.

The semiconductor device 100 includes a memory array 118. The memory array 118 is organized into a plurality of memory banks. In the embodiment of FIG. 1, the memory array 118 is shown as including N memory banks labeled BANK0 to BANKN-1. For example, a memory array 118 may include 4, 8, 16, 32 or any other number of memory banks. More or fewer banks may be included in the memory array 118 of other embodiments.

Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank.

The bit lines BL are coupled to a respective sense amplifier (SAMP). Read data from the bit line BL is amplified by the sense amplifier SAMP, and transferred to read/write amplifier (RWAMP) circuit 120 over local data lines (LIO), transfer gate (TG), and global data lines (GIO). Conversely, write data outputted from the RWAMP circuit 120 is transferred to the sense amplifier SAMP over the complementary main data lines GIO, the transfer gate TG, and the complementary local data lines LIO, and written in the memory cell MC coupled to the bit line BL.

The semiconductor device 100 may employ a plurality of external terminals, such as solder pads, that include command and address (C/A or CA) terminals coupled to a command and address bus to receive commands and addresses, clock terminals to receive clocks CK and /CK, data terminals DQ coupled to a data bus to provide data, and power supply terminals to receive power supply potentials VDD, VSS, VDDQ, and VSSQ. The external terminals may also generally be referred to as ‘pins’ such as C/A pins. In some embodiments, the external terminals may couple directly to a host or controller of the memory device 100. In some embodiments, the external terminals may couple to various buses/connectors of a module or other package. In some embodiments, each terminal may generally receive a first voltage which represents a logical high or a second voltage which represents a logical low. Other schemes, such as multi-level signaling (e.g., PAM4) may be used in other example embodiments.

The clock terminals are supplied with external clocks CK and /CK that are provided to an input circuit 112. The external clocks may be complementary. The input circuit 112 generates an internal clock ICLK based on the CK and /CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may act as external connections to the device 100).

The C/A terminals may be supplied with memory addresses. The memory addresses supplied to the C/A terminals are transferred, via a command and address input circuit 102, to an address decoder 104. The address decoder 104 decodes the address into a bank address, row address, and column address. The bank address BADD selects the row decoder 108 and column decoder 110 and thus selects the bank. The address decoder 104 supplies a decoded row address XADD to the row decoder 108 selected by BADD and supplies a decoded column address YADD to the column decoder 110 selected by BADD. The decoded row address XADD may be used to determine which row is opened or activated, coupling the memory cells along the activated word line to the intersecting bit lines. The column decoder 110 provides a column select signal CS based on the column address YADD. The CS signal selects which bit lines are coupled to local input/output lines, allowing those bit lines to be accessed.

The C/A terminals may be supplied with commands. Examples of commands include timing commands for controlling the timing of various operations, access commands for accessing the memory, such as row activation commands, read commands for performing read operations, write commands for performing write operations, and pre-charge commands, refresh commands such as all-bank refresh, same bank refresh, dual-bank refresh, and per-bank refresh, as well as other commands and operations. The access commands may be associated with one or more row address XADD, column address YADD, and bank address BADD to indicate the memory cell(s) to be accessed. In some embodiments, the command and address may be transmitted together as a command packet along the C/A terminals. The input circuit 102 separates the command portion of the packet from the address portion and provides the command portion to the command decoder 106 and the address portion to the address decoder 104. An example access command includes an activation command packet ACT, which includes the activation command, row address, and bank address, which may be followed by column commands which include a column address and commands such as read or write.

The memory device 100 may receive a normal access command or a linked access command. The normal row activation command ACTN causes the memory to perform an access operation on a bank specified by a bank address BADD. The linked row activation command ACTL causes the memory to perform an access operation on a bank specified by the bank address BADD and gives memory the opportunity to perform a linked refresh operation in one or more banks linked to the bank specified by BADD. In some embodiments, which bank is given the linked refresh opportunity may be inherent to the structure of the memory. In some embodiments, the memory device 100 may receive a linked bank address BADDL which indicates which bank in the linked group of banks is being given the linked refresh opportunity. In some embodiments, the memory device 100 may receive a linked bank address BADDL which additionally indicates which of the banks are linked with the bank specified by BADD.

The commands may be provided as internal command signals to a command decoder 106 via the command and address input circuit 102. The command decoder 106 includes circuits to decode the internal command signals to generate various internal signals and commands for performing operations. For example, the command decoder 106 may provide signals to indicate if data is to be read, written, etc. Responsive to an activation command received at the C/A terminals, as part of an access operation the command decoder 106 provides an internal activation command or internal activation signal ACT to the bank or banks that the command is directed to. Responsive to a pre-charge command the command decoder 106 provides an internal pre-charge command or internal pre-charge signal Pre to the bank. The row decoder 108 of the targeted bank(s) activates a word line responsive to the internal activation signal ACT and deactivates (or pre-charges) the word line responsive to the internal pre-charge signal Pre.

In an example write operation, the device 100 writes data received at the DQ terminals to the memory cells specified by a received bank, row and column address. As part of the write operation, the command decoder 106 receives an activation command ACTN or ACTL and a write command and provides internal signals such as W and ACTN/ACTL/Pre. The write data is received by the IO circuit 122 and provided to the RWAMP circuit 120. The row decoder 108 selected by BADD activates the row selected by XADD responsive to the internal activation signal ACTN or ACTL. The column decoder 110 selected by BADD couples the bit lines selected by YADD to the LIO and GIO lines to the RWAMP circuit 120. The sense amplifiers drive the voltages on the coupled bit lines to write the write data to the memory cells at the intersection with the active word line. If the command was a linked activation command and ACTL is provided, then the refresh control circuit 116 of a linked bank, for example as specified by BADDL, may perform one or more refresh operations.

In an example read operation, the device 100 reads data from the memory cells specified by a received bank, row, and column address and provides that read data to the DQ terminals. As part of the read operation, the command decoder 106 receives an activation command ACTN or ACTL and a read command and provides internal signals such as a read signal R, and ACTN/ACTL/Pre. The row decoder 108 selected by BADD activates the row selected by XADD responsive to the internal row activation signal ACT. The column decoder 110 selected by BADD couples the bit lines selected by YADD to the LIO and GIO lines to the RWAMP circuit 120. The RWAMP circuit 120 provides the read data to the IO circuit 122 and the IO circuit 122 provides the read data to the DQ terminals. If the command was a linked activation command and ACTL is provided, then the refresh control circuit 116 of a linked bank, for example as specified by BADDL, may perform one or more refresh operations.

The device 100 includes a refresh control circuit 116. The refresh control circuit 116 includes a refresh address generator, such as a counter circuit, which generates refresh addresses. For example, the refresh address generator may use sequential logic to generate the refresh address, such as RXADD(i+1) = RXADD(i) + 1. The refresh address generator is shared by multiple of the banks 118. In some embodiments, there may be one refresh address generator for all of the banks. When a refresh operation is performed, the command decoder 106 provides a refresh signal, such as REF to the bank or banks where the refresh is being performed. Responsive to the refresh signal REF, the refresh control circuit 116 provides a refresh address RXADD as a row address along a row address bus.

The row address XADD includes one or more bits which make up a refresh address flag. If the flag is inactive (e.g., the refresh address flag bit is in a low logical state) then it indicates the address is used for normal operations such as access operations. If the flag is active (e.g., the refresh address flag bit is in a high logical state) then it indicates the address is a refresh address RXADD.

The command decoder provides signals to the bank or banks indicated by the command. Responsive to an activation signal to a bank, a row address latch 109 of that bank’s row decoder 108 latches the address on the bus. If the bank has received a refresh signal, the latch 109 will latch an address that has an active refresh address flag. If the bank has not received a refresh signal, the latch will latch an address that has an inactive refresh address flag. In this way the same bus may used by both row addresses for access commands and refresh addresses even in circumstances multiple banks receive activation signals at a same time.

The command decoder 106 includes a dynamic refresh timer circuit 107. The dynamic refresh timer circuit generates and provides signals to the bank logic circuits (e.g., the row decoder 108) to control that bank during refresh operations. Certain refresh commands may be received while previous refresh operations in the memory are still ongoing. For example, a refresh command may be received for a bank while a different bank is being refreshed (e.g., due to a previous command). The dynamic refresh timer circuit 107 assigns an array timer circuit for the refresh operations and the array timer circuit provides signals such as ACT to the targeted bank(s) for a designated period of time. Since there are multiple array timers, and since they are assigned based on need, multiple overlapping refresh commands may be accommodated.

The power supply terminals are supplied with power supply potentials VDD and VSS. The power supply potentials VDD and VSS are supplied to an internal voltage generator circuit 124. The internal voltage generator circuit 124 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

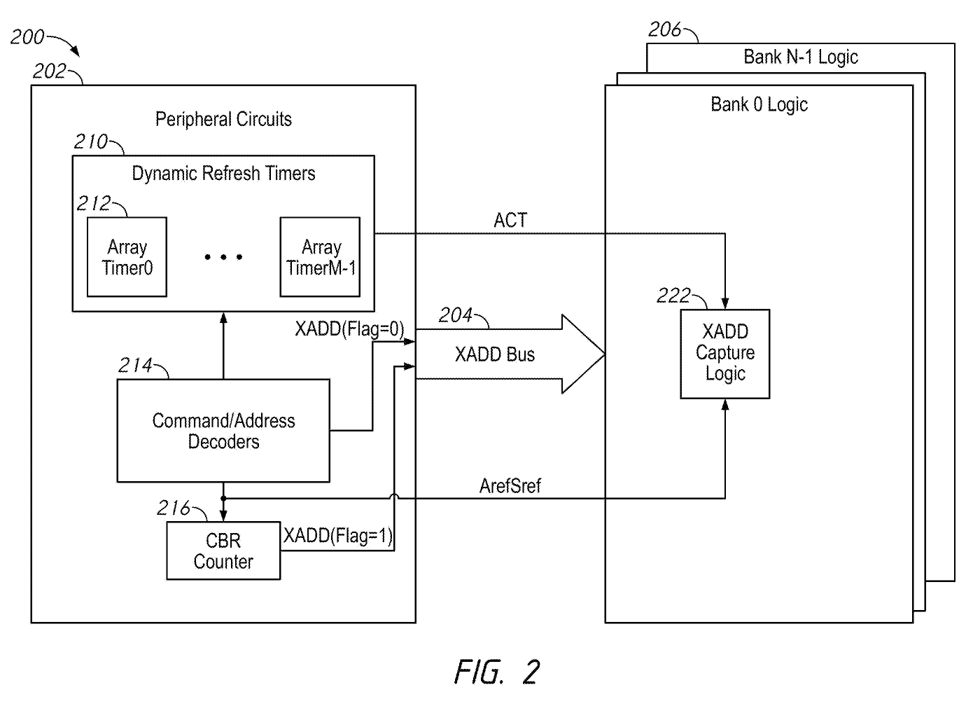

FIG. 2 is block diagram of bank operation logic according to some embodiments of the present disclosure. The bank operation logic 200 may represent selected components of a memory device, such as the memory device 100 of FIG. 1. FIG. 2 shows certain components useful to describe how commands and row addresses are sent to the banks.

FIG. 2 shows a certain peripheral circuits 202 which are shared amongst all the banks, as well as bank logic regions 206. The bank logic regions 206 include logic circuits, such as row decoders (e.g., 108 of FIG. 1) and column decoders (e.g., 110 of FIG. 1) which are specific to that bank. The peripheral circuits include dynamic refresh timer circuit 210 (e.g., dynamic refresh timer 107 of FIG. 1), a refresh address counter circuit 216 (e.g., which may be part of a refresh control circuit 116 of FIG. 1), and command and address decoders 214 (e.g., 102, 104, and/or 106 of FIG. 1).

When a command is received which causes a refresh operation, such as an explicit refresh command (e.g., REFdb) or a linked activation command ACTL, the command/address decoders 214 provide signals to the dynamic refresh timer circuits 210. The dynamic refresh timer circuits 210 include a number of array timers 212, each of which may be used to provide activation signals, such as ACT, to one or more banks as part of a refresh operation. When the command/address decoders 214 signal that a refresh operation is occurring, the dynamic refresh timer circuits 210 assigns one of the array timers 212 to generate the activation signals for the bank(s) associated with that refresh operation.

The command/address decoders receive access commands along with a row address. The command address decoder appends a refresh address flag (e.g., a refresh address bit) in an inactive state to that row address and provides it to the row address bus 204. If the command calls for a refresh (e.g., either through an explicit refresh command or through a linked activation command) then the command/address decoders 214 sends a refresh signal ArefSref to the refresh address generator 216 to generate a refresh address. The refresh address generator circuit 216 generates a row address with the refresh address flag in an active state and provides that address to the row address bus 204.

The row address bus 204 is coupled in common to the logic of the banks 206. The activation signals ACT and refresh signals ArefSref are specific for each bank. For example, if there are N banks, there may be N activation signals and N refresh signals. Each bank receives a respective activation signal ACT and a respective refresh signal ArefSref. If ACT is active but ArefSref is inactive, it indicates an access operation for that bank. If both ACT and ArefSref are active, it indicates a refresh operation. If neither are active it indicates the current bank is not being operated upon.

Each bank logic includes row address capture logic circuits 222 which determine when to capture an address from the row address bus 204 and whether or not to capture a current address based on a state of the refresh address flag. When the row address capture logic 222 receives the activation signal ACT for that bank from the peripheral circuits 202, if that bank is not receiving the refresh signal (e.g., ArefSref for that bank is inactive), then it will capture the address on the bus 204 as long as it has a refresh address flag which is inactive. When the row address capture logic 222 receives the activation signal ACT for that bank and also the refresh signal (e.g., ArefSref for that bank is active), then it will capture the address on the bus 204 as long as it has an active refresh address flag. If the state of the refresh signal and the refresh flag do not match (e.g., the flag is active but ArefSref is inactive or vice versa) then the bank will not capture the address, even if ACT is active for that bank.

In some embodiments, the bank operation logic 200 may use dynamic refresh timer circuits 210 with multiple timers 212, but without using refresh address flags in the row addresses. For example, there may still be a dynamic refresh timer circuit, but the refresh address generator may be moved to the bank logic 206 and repeated on a bank by bank basis and the addresses along the bus 204 are only used for access operations and thus do not have a refresh address flag. In some embodiments, the memory device 200 may use row addresses with refresh address flags, but use fixed bank refresh logic. For example, the memory may have a single array timer 212 for the banks, or array timers which are assigned to fixed subsets of the banks, such as an even bank array timer and an odd bank array timer. In some embodiments, such as the one shown in FIG. 2, the memory may use both dynamic refresh timer logic and refresh address flags.

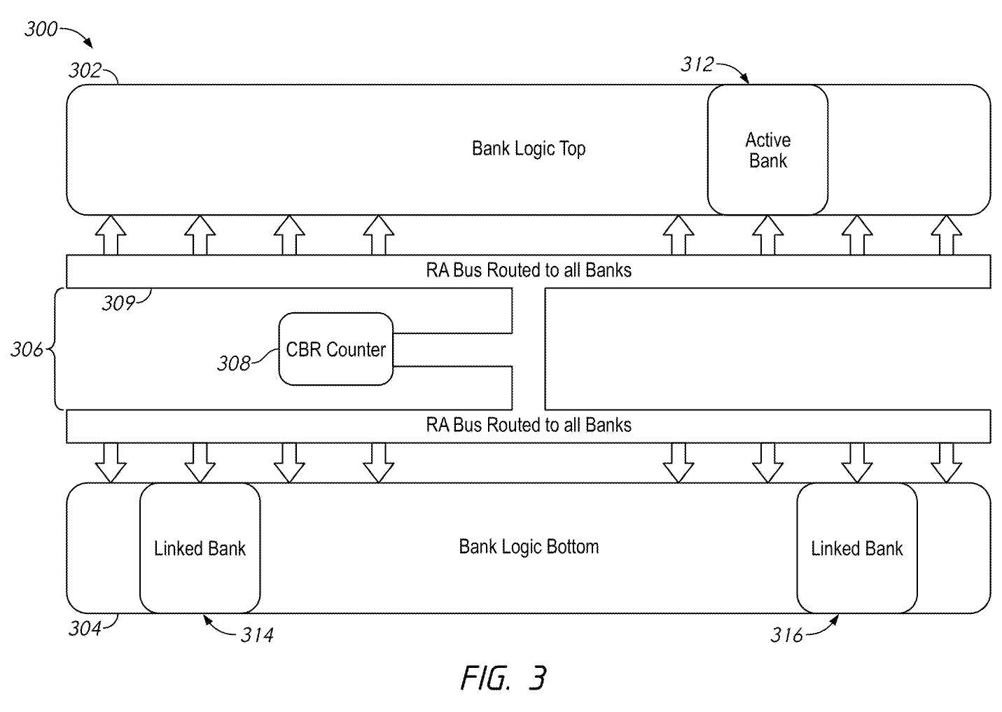

FIG. 3 is a block diagram of an example layout of a memory device according to some embodiments of the present disclosure. The memory device 300 may, in some embodiments, implement the memory device 100 of FIG. 1 and/or the bank operation logic 200 of FIG. 2. The memory device 300 shows a simplified layout of certain components related to bank operations.

The memory device 300 includes a first bank logic region 302 and a second bank logic region 304. Each of the bank logic regions 302 and 304 includes a number of banks and their associated logic (e.g., 206 of FIG. 2) such as row decoders and column decoders. A peripheral region 306 (e.g., 202 of FIG. 2) is positioned between the two bank regions 302 and 304. The peripheral region 306 includes circuits which are generally shared by the banks and their logic.

FIG. 3 shows a refresh address generator circuit 308 (e.g., part of refresh control circuit 116 of FIG. 1 and/or the refresh address generator circuit 216 of FIG. 2) and a row address bus 309 (e.g., 204 of FIG. 2). When the refresh address generator 308 generates a refresh address, it is provided along the row address bus 309 to one or more banks in region 302, region 304, or both. Signals (not shown in FIG. 3) such as an activation signal ACT, a refresh signal such as ArefSref, or both, are sent on a bank-by-bank basis to indicate which bank or banks are being activated and if a refresh operation is being performed in that bank or not.

In an example operation, a linked activation command ACTL is received with a bank address indicating the bank 312 in region 302. The row address received with that command is sent along the row address bus 309 with an inactive refresh address flag and an activation signal is sent to the bank 312. Since the command is a linked activation command, the memory may also perform a refresh operation responsive to the command ACTL. In this case, a refresh operation is performed on the bank 314. The refresh address generator 308 generates a refresh address with an active refresh address flag and provides it along the row address bus 309 and an activation signal and a refresh signal are sent to the bank 314. Both banks will receive both row addresses, since they are coupled in common to the row address bus 309. The bank 312 will latch the address with the inactive refresh address flag since the bank 312 did not receive a refresh signal, while the bank 314 will latch the refresh address with the active refresh address flag since the bank 314 received a refresh signal.

In an example operation, the memory device 300 may receive a dual-bank refresh command REFdb. The REFdb command indicates banks 314 and 316. Both banks will receive a refresh signal. The refresh address generator 308 generates a refresh address and provides it along the bus 309. An activation signal is sent to the bank 314 at a first time and so it latches the refresh address at the first time. An activation signal is sent to the bank 316 at a second time and so it latches the refresh address at the second time.

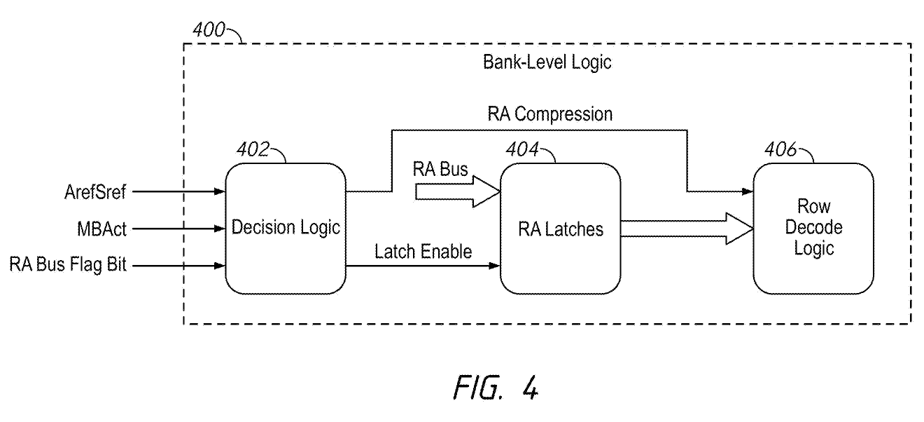

FIG. 4 is a block diagram of row address capture logic for a bank according to some example embodiments of the current disclosure. The row address capture logic 400 of FIG. 4 may, in some embodiments implement the row address capture logic 222 of FIG. 2. The row address capture logic 400 of FIG. 4 may represent bank logic for a specific bank of the array and may be repeated on a bank-by-bank basis.

The row address capture logic 400 includes decision logic 402, row address latches 404 (e.g., 109 of FIG. 1), and row decoder logic 406 (e.g., 108 of FIG. 1). The decision logic receives a bank activation signal MBAct, a refresh signal ArefSref and a refresh address flag of the row address. The decision logic 402 provides a latch enable signal to the row address latches 404. When the latch enable signal is active, the row address latches 404 capture the row address currently on the row address bus (e.g., 204 of FIG. 2 and/or 309 of FIG. 3). The row decoder logic 406 uses the address in the row address latches 404 to determine which word line or word lines to activate.

The decision logic 402 receives bank activation signal MBAct and bank refresh signal ArefSref. The signal MBAct is active when some kind of operation is being performed on the bank. The signal ArefSref is active when a refresh operation is being performed on the bank. The decision logic 402 also receives a refresh address flag of the row address currently on the row address bus. For example, the refresh address flag may be a single bit added to the row address which is in a first state (e.g., a logical high) when the refresh address flag is active or a second state (e.g., a logical low) when the refresh address flag is inactive. When MBAct becomes active, if the refresh address flag is inactive and the signal ArefSref is inactive, then the decision logic 402 provides the signal latch enable. When MBAct becomes active, if the refresh address flag is active and the signal ArefSref is active, then the decision logic 402 provides the signal latch enable. If ArefSref and the refresh address flag have opposite states (e.g., one is active and the other is not) then even if MBAct is active, the decision logic 402 will not provide the latch enable signal.

When the latch enable signal is active, the row address latches 404 will capture the current address on the row address bus. The row decode logic 406 will then use that address to determine which word lines to activate, for example by decoding the latched address into signals such as MWL and FX which select sub-word line drivers. In some embodiments, the row address latches 404 do not latch the refresh address flag bit(s) of the row address.

In the embodiment of FIG. 4, multiple word lines may be refreshed at the same time as part of a refresh operation. One or more bits of the refresh address may be masked and the word lines which share the remaining portion of the address in common may be refreshed together. For example, if two bits are masked, then four word lines will be refreshed together. In such embodiments, the decision logic 402 provides a row address compression signal if ArefSref is active. Responsive to the row address compression signal, the row decode logic 406 will mask one or more bits of the latched row address in the latches 404 when it begins to decode the address.

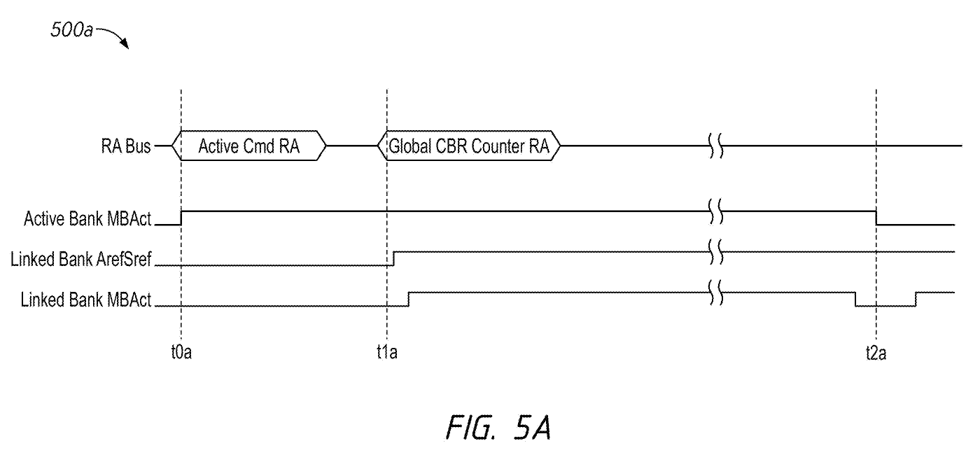

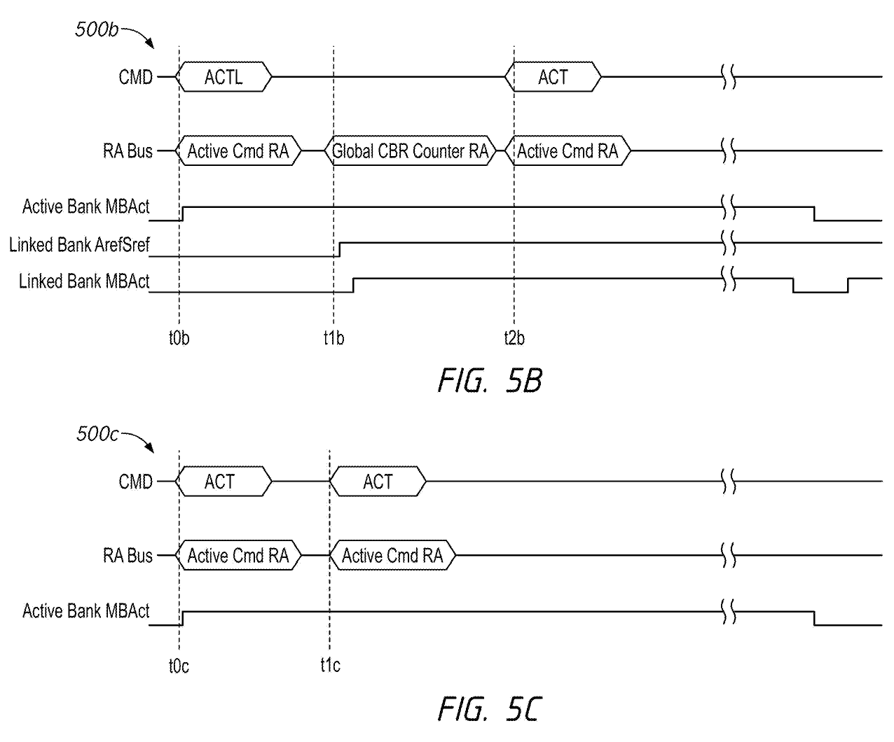

FIGS. 5A-5C are timing diagrams of access operations in an example memory device according to some embodiments of the present disclosure. The timing diagrams represent operations that may be performed in a memory device such as 100 of FIGS. 1, 300 of FIG. 3, portions thereof such as 200 of FIGS. 2, 400 of FIG. 4, or combinations thereof.

The timing diagram 500a of FIG. 5A shows signals in a memory device after a linked activation command ACTL is received. The timing diagram 500b of FIG. 5B shows a signals in a memory device that receives an ACTL command and then a subsequent normal activation ACT command. The timing diagram 500c shows signals in a memory device when it receives two consecutive normal activation commands ACT. Each of the timing diagrams 500a, 500b, and 500c show addresses along a row address bus (e.g., 204 of FIG. 2 and/or 309 of FIG. 3), a bank activation signal MBAct for the bank associated with the bank address received along with the activation command ACTL or ACT, a refresh signal ArefSref a linked bank which is being refreshed, and a bank activation signal MBAct for the bank being refreshed. The timing diagrams 500b and 500c also show a command bus.

The timing diagram 500a shows a linked activation command ACTL being received at a time t0a. Responsive to that, the row address received along with the command (the ‘Active Cmd RA’) is provided along the row address bus, and the activation signal MBAct for the bank indicated by the bank address received with ACTL (the ‘Active Bank MBAct’) starts being provided. The row address will be latched by the row address capture logic for that bank, since the refresh signal for that bank (not shown) is inactive, and the row address has an inactive refresh address flag. At a time t1a, the refresh address generator (e.g., 116 of FIGS. 1, 216 of FIG. 2, and/or 308 of FIG. 3) provides a refresh address (‘Global CBR counter RA’) along the row address bus. At time t1a the refresh signal ArefSref is also provided to the linked bank which is being refreshed (‘Linked Bank ArefSref’) and the activation signal is provided to that bank (“Linked Bank MBAct’). At t1a, even though the first bank is still receiving the MBAct signal, it will not latch the Global CBR counter RA, because that bank is not receiving ArefSref, and the refresh address flag of Global CBR counter RA is active. However, the linked bank for refreshing will latch that address since it is receiving Linked Bank ArefSref.

The timing diagram 500b is generally similar to the timing diagram 500a, except that the timing diagram 500b includes a second activation command being received. Similar to the times t0a and t1a of FIG. 5A, the timing diagram 500b includes a linked activation command ACTL being received at time t0b, and a refresh operation being performed at a time t1b. At a time t2b, the memory device receives a normal (non-linked) activation command with a bank address that specifies the same bank as the linked activation command received at t0b. At the time t2b, the row address received along with ACT is provided along the row address bus. Since the signal Active Bank MBAct is still active, the row decoder will latch the second Active Cmd RA since it has an inactive refresh address flag. Even though the signal Linked Bank MBAct is also active at t2b, because Linked Bank ArefSref is active, the linked bank logic will not latch the second Active Cmd RA since its refresh address flag is inactive. The commands ACTL and ACT are separated by a time tRRD (the time between t0b and t2b).

The timing diagram 500c shows two normal (non linked) activation commands being received at the times t0C and t1C respectively. A first Active Cmd RA is provided along the row address bus at the time t0C and an activation signal MbACT is sent to the bank associated with the first activation command. A second Active Cmd RA is provided along the row address bus at a time t1c. An MbACT for the second active command is not shown in the diagram 500c, but would be similar to the signal for the first bank, but becoming active at the time t1c. The times t0c and t1c are separated by a shortened time tRRD_S which is shorter than tRRD, since no linked operation is performed.

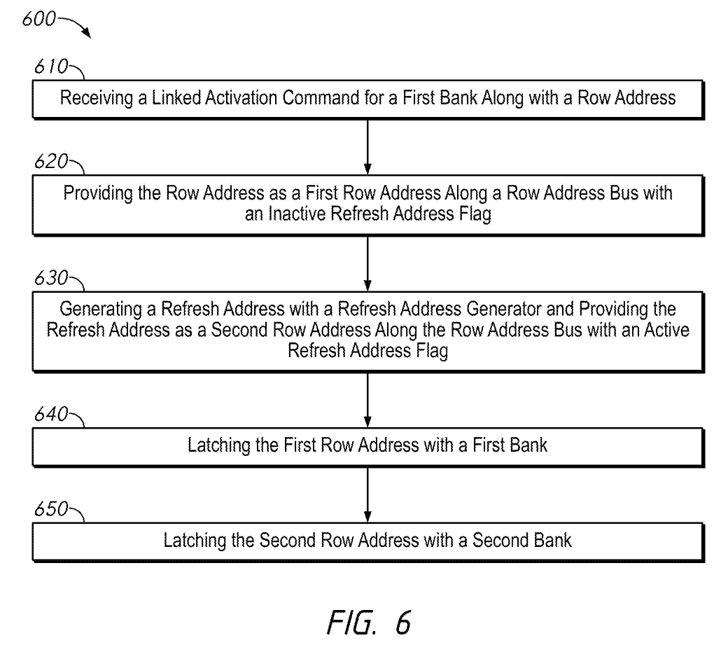

FIG. 6 is a flow chart of a method of sharing a row address bus for access operations and refresh operations according to some embodiments of the present disclosure. The method 600 of FIG. 6, may, in some embodiments, be implemented by one or more of the apparatuses described herein. For example, the method 600 may be implemented by the memory device 100 of FIGS. 1, 200 of FIGS. 2, 300 of Figure, and/or 400 of FIG. 4.

The method 600 may begin with box 610, which describes receiving a linked activation command for a first bank along with a row address. The method may include receiving the linked activation command ACTL along C/A terminals of the device. The linked activation command ACTL may include a row address and a bank address as part of a command packet. In some embodiments, the linked activation command may also indicate a second bank for a refresh operation. In some embodiments, method may include selecting the second bank from a group of banks linked to the first bank.

Box 610 may generally be followed by box 620, which describes providing the row address as a first row address along a row address bus (e.g., 204 of FIG. 2 and/or 309 of FIG. 3) with an inactive refresh address flag. The method 620 may include appending one or more refresh address flag bits to the received row address and setting them at a logical level(s) to indicate an inactive flag. The method 600 may include providing the first row address in common to a plurality of banks along the row address bus.

Box 620 may generally be followed by box 630, which describes generating a refresh address with a refresh address generator (e.g., 116 of FIG. 1 and/or 216 of FIG. 2) and providing the refresh address as a second row address along the row address bus with an active refresh address flag. The method 600 may include generating the refresh address with a counter circuit and appending one or more refresh flag bits to the generated address with a state(s) that indicate an active refresh address flag.

Box 630 may generally be followed by box 640, which describes latching the first row address off the row address bus with the first bank and box 650, which describes latching the second row address off the row address bus with the second bank. The method 600 may include providing an active activation signal and an inactive refresh signal to the first bank and providing an active activation signal and an active refresh signal to the second bank. The method 600 may include latching the first row address with the first bank responsive to the active activation signal and the inactive refresh signal and the first row address having an inactive refresh flag. The method 600 may include latching the second row address with the second bank responsive to the active activation signal and the active refresh signal and the first row address having an active refresh flag. The method may include not latching the first row address with the second bank and not latching the second row address with the first bank. The method 600 may include latching the first row address with the first bank at a first time and latching the second row address with the second bank at a second time.

In some embodiments, the method 600 may include compressing the second row address with the second bank responsive to the refresh signal. For example the method may include masking one or more bits of the row address and refreshing multiple word lines that share the non-masked portion of the row address in common.

In some embodiments, the method 600 may include receiving a refresh command for a third bank after receiving the linked activation command, but while the refresh operation for the second bank is still being performed. The method 600 may include assigning a first array timer (e.g., 212 of FIG. 2) to provide an activation signal to the second bank and assigning a second array timer to provide an activation signal to the third bank. The method 600 may include determining that the second array timer is inactive when the refresh command is received.

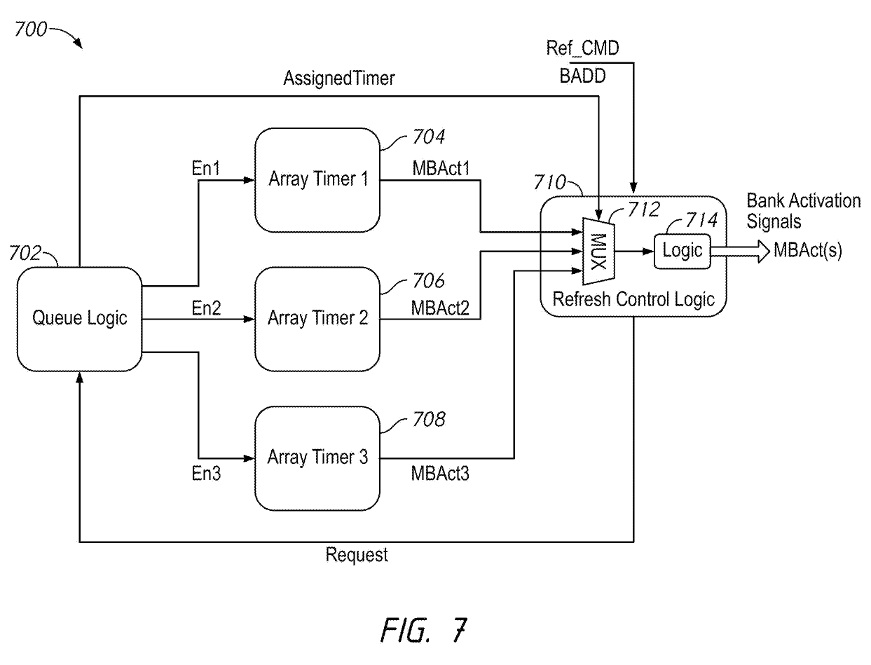

FIG. 7 is a block diagram of a dynamic refresh timer logic circuit according to some embodiments of the present disclosure. The dynamic refresh timer logic circuit 700 may, in some embodiments, implement the dynamic refresh timer circuit 107 of FIG. 1 and/or the bank activation logic circuit 210 of FIG. 2.

The dynamic refresh timer circuit 700 includes a number of array timers. In the example implementation of FIG. 7 there are 3 array timers 704, 706, and 708. More or fewer timers may be used in other example embodiments. The number of timers may be based, at least in part, on the maximum number of bank operations the memory device is capable of performing at overlapping times.

The dynamic refresh timer circuit 700 includes a queue logic circuit which determines which array timers to enable, the array timers 704, 706, and 708, and control logic circuits 710 which provide the signals to the banks. The control logic 710 includes a multiplexer 712 and logic circuits 714.

The control logic 710 receives a refresh command Ref_CMD, indicating that a refresh operation should occur. The refresh command Ref_CMD may be a stand alone refresh command such as REFdb or it may be a command such as ACTL that causes a refresh operation to occur. The refresh command Ref_CMD comes with a bank address BADD which indicates which bank or bank(s) are being refreshed. The refresh control logic circuit 710 provides an activation signal to the refreshing bank for the duration of the refresh operation. For example, responsive to a REFdb command, the refresh control logic 710 will provide an activation signal to a first refreshed bank for a period of time and then provide an activation signal to a second refreshed bank for the period of time. The array timers 704 generate the activation signal for the requisite period of time and the refresh control logic 710 routes the activation signal to the associated bank. In some situations, such as REFdb operations, where two refresh operations are sequential in different banks, a single timer 704, 706, or 708 may provide activation signals for both banks. For example the assigned timer may provide an activation signal for a first period of time and the control logic 710 sends it to a first bank, and then the assigned timer may provide the activation signal for a second period of time and the control logic 710 sends it to a second bank.

The dynamic refresh timer circuit 700 dynamically assigns timers 704, 706, and 708 to different refresh operations as needed. When the refresh control logic circuit 710 receives a refresh command Ref_CMD, it sends a request signal Request to the queue logic 702. The queue logic 702 tracks which array timer(s) are currently in use. Responsive to the request signal, the queue logic 702 assigns one of the array timers 704, 706, or 708 to generate signals for the refresh operation associated with the current Ref_CMD. The queue logic 702 provides an enable signal En1, En2, and En3 for each of the array timers 704, 706, and 708 respectively. When the enable signal for a timer is active, the associated array timer begins providing an activation signal MBAct1, MBAct2, or MBAct3 respectively for a period of time. The period of time is based on the length of the refresh operation. The queue logic 702 tracks which array timers 704, 706, and/or 708 are enabled based on which enable signals are active. Responsive to the request signal, the queue logic 702 activates a previously inactive one of the enable signals and sends an assigned timer signal AssignedTimer back to the control logic 710 indicating which timer was just activated.

The multiplexer 712 receives the signal AssignedTimer indicating which timer was assigned to the current refresh command. The activation signal from that timer is provided to the logic circuit 714 which provides that signal as MBAct to the bank associated with the operation(s) for the refresh command for a period of time based on the array timer assigned to that operation. When the array timer stops providing the activation signal its enable signal becomes inactive. Accordingly, when a new request is sent by the logic 710, the queue logic 702 may reassign that timer to a new task.

In an example operation, the dynamic refresh timer circuit 700 is idle, with no array timers 704, 706, or 708 assigned, when a linked activation command ACTL is received with a bank address indicating that the refresh operation should be performed on a first bank. The refresh control logic circuit 710 sends the signal Request to the queue logic 702. Since no array timers 704, 706, and 708 are in use, all the enable signal En1, En2, and En3 are inactive. The queue logic 702 assigns the first array timer 704 to the operation and begins providing En1. It also provides the signal AssignedTimer indicating timer 1. The array timer 704 begins providing MBAct1 and the multiplexer 712 routes that to the logic 714, which routes the signal MBAct1 to the first bank. When a second refresh command indicating a second bank is received, the logic 710 provides the signal Request again. The queue 702 cannot use the array timer 704 because it is already in use for the ACTL command so it assigns the second timer 706 and begins providing En2. The queue logic 702 also provides AssignedTimer indicating timer 2. The array timer 706 begins providing MBAct2 and the refresh control circuit 710 begins providing MBAct2 as an activation signal to the second bank.

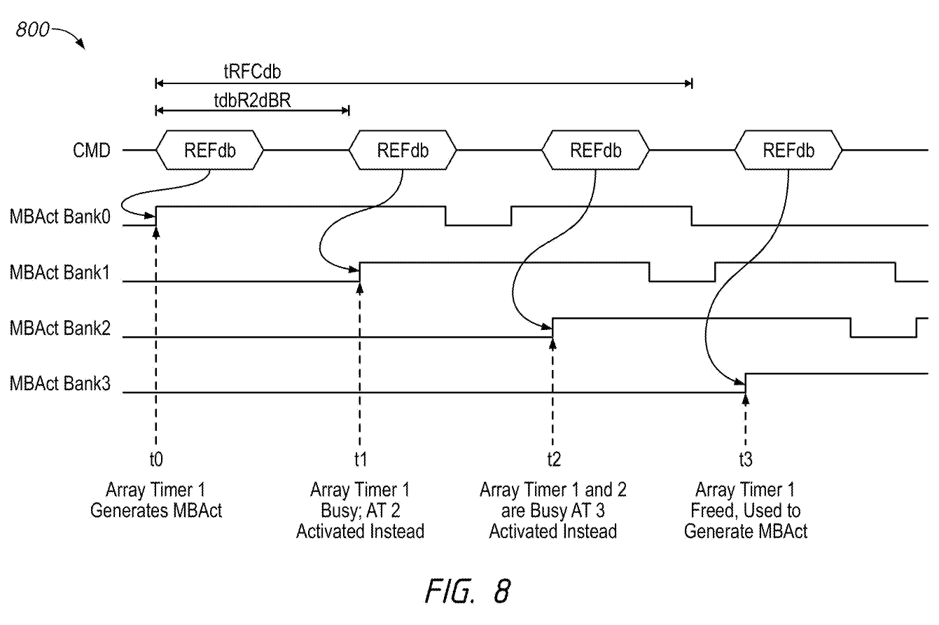

FIG. 8 is a timing diagram of overlapping refresh operations using a dynamic refresh timer circuit according to some embodiments of the current disclosure. The timing diagram 800 shows operations in a memory device, such as 100 of FIG. 1, which includes a dynamic refresh timer circuit such as 107 of FIGS. 1, 210 of FIG. 2, and/or 700 of FIG. 7. In particular, the timing diagram 800 is described with respect to a dynamic refresh timer circuit with three activation timers, similar to the one described in FIG. 7.

The timing diagram 800 shows signals along a command bus, and bank activation signals for four different banks Bank0 to Bank3. The memory device receives a sequence of REFdb commands. Each REFdb command comes with a bank address and causes two refresh operations to be sequentially in a first bank and a second bank. For the sake of simplicity, only the first bank of each pair is listed, however two banks may be refreshed for each operation. Each REFdb operation lasts for a time tRFCdb. However, sequential REFdb commands may be received with the timing tdbR2dBR which is shorter than tRFCdb. Accordingly, REFdb operations may overlap with each other.

At a time t0, the first REFdb command is received for the first bank Bank0. In this example, it is assumed that no array timer is in use at the time t0, so when the logic (e.g., 710 of FIG. 7) requests an array timer, the queue logic (e.g., 702 of FIG. 7) assigns the first timer (e.g., 704 of FIG. 7) to provide MBAct Bank0. At a time t1, a second REFdb command is received. Since MBAct Bank0 is still being provided when the logic requests an array timer, the queue logic assigns the second timer (e.g., 706 of FIG. 7) to provide MBAct Bank1. At a time t2, a third REFdb command is received. Since MBAct Bank0 and MBAct Bank1 are both still being provided, the queue logic assigns the third timer (e.g., 708 of FIG. 7) to provide MBAct Bank2. At a time t3, a fourth REFdb command is received. At this point, the operations performed responsive to the first REFdb command on Bank0 have ended. Accordingly, at the time t3, the queue logic assigns the first array timer to begin providing MBAct Bank3.

While the operation of the dynamic activation timer is generally described with respect to sequential REFdb commands, other overlapping commands may also use the dynamic activation timer in an analogous ways. For example, multiple ACTL commands may use the dynamic activation timers to handle the overlapping access and refresh operations. Similarly, if an ACTL command is followed by other commands, such as REFdb, there may be overlapping operations. In general, any command that causes refreshes of fewer than all the banks (e.g., commands other than REFab) may allow for overlapping commands.

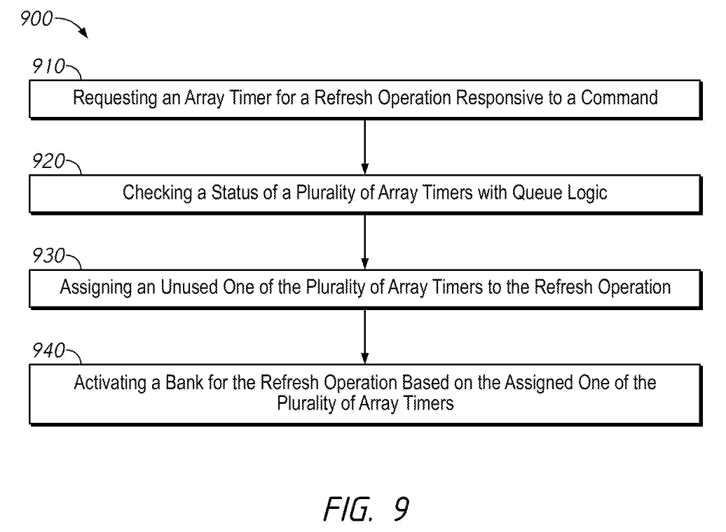

FIG. 9 is a flow chart of a method of dynamically assigning array timers for refresh operations according to some embodiments of the present disclosure. The method 900 may, in some embodiments, be implemented by one or more of the apparatuses or systems described herein. For example, by the dynamic refresh timer circuit 107 of FIGS. 1, 210 of FIG. 2, and/or 700 of FIG. 7.

The method 900 begins with box 910 which describes requesting an array timer (e.g., 212 of FIG. 2 and/or 704, 706, or 708 of FIG. 7) for a refresh operation responsive to a command. The method 900 may include receiving the command which indicates a refresh operation. The command may be received by a refresh control logic circuit (e.g., 710 of FIG. 7). The command may be a linked activation command or an explicit refresh command such as REFdb. The method 900 may include providing a refresh signal from refresh control logic (e.g., 710 of FIG. 7) responsive to the command.

Box 910 may be followed by box 920, which describes checking a status of a plurality of array timers with queue logic (e.g., 702 of FIG. 7). For example the method 900 may include checking the status responsive to the request signal. The method may include determining the status based on the states of a respective enable signal for each of the plurality of array timers.

Box 920 may be followed by box 930, which describes assigning an unused one of the plurality of array timers to the refresh operation. The assigning may include providing the enable signal to the assigned timer and providing a timer assigned signal to the refresh control logic circuit. The timer assigned signal indicates which array timer was assigned. The method 900 may include providing an activation signal from the assigned one of the plurality of timers responsive to the enable signal.

Box 930 may be followed by box 940, which describes activating a bank for the refresh operation based on the assigned one of the plurality of array timers. For example, the method 900 may include receiving a bank address with the command. The method 900 may include routing the activation signal from the assigned one of the plurality of the array timers to one or more banks associated with the bank address. The routing may be performed by the refresh control logic circuit. In some embodiments, where the command is a REFdb command, the method 900 may include routing the activation signal from the assigned one of the plurality of array timers to a first bank for a first period of time and providing the activation signal from the assigned one of the plurality of array timers to a second bank for a second period of time.

The method 900 may include receiving a second command and requesting an array timer for a second refresh operation responsive to the second command. The method 900 may include checking the status of the plurality of array timers with the queue logic responsive to the second request. The method 900 may include assigning a different one of the plurality of array timers for the second refresh operation when the assigned one of the plurality of array timers is still in use. The method 900 may include activating another bank for the second refresh operation based on the assigned different one of the plurality of array timers.

In some embodiments, the method 900 may include providing the activation signal to the bank along with a refresh signal. The method 900 may include latching an address with an active refresh address flag off a row address bus responsive to the activation signal and the refresh signal. The method 900 may include not latching an address with an inactive refresh address flag responsive to the activation signal and the active refresh signal.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a plurality of memory banks;
a plurality of row address capture logic circuits, each associated with one of the plurality of memory banks;
a row address bus coupled in common to the plurality of row address capture logic circuits;
a refresh address generator configured to provide a refresh address along the row address bus, wherein the refresh address includes an active row address flag,
wherein each of the plurality of row address capture logic circuits is configured to capture an address off the row address bus if the address has an active row address flag and the memory bank associated with the row address capture logic circuit receives an activation signal and a refresh signal.

2. The apparatus of claim 1, wherein each of the plurality of row address capture logic circuits are configured to not capture the address if the address has an active refresh address flag but the row address capture logic circuit does not receive a refresh signal.

3. The apparatus of claim 1, further comprising:
an address decoder configured to receive a row address as part of an access operation and provide the row address along the row address bus with an inactive refresh address flag,
wherein each of the row capture logic circuits is configured to capture an address off the row address bus if the address has an inactive row address flag and the memory bank associated with the row address capture logic circuit receives an activation signal and an inactive refresh signal.

4. The apparatus of claim 1, further comprising a command decoder configured to provide the activation signal to one or more selected ones of the plurality of memory banks as part of an access operation or a refresh operation.

5. The apparatus of claim 1, wherein the refresh address generator is located in a peripheral region of the apparatus.

6. The apparatus of claim 1, wherein the refresh address flag is an extra bit on the row address.

7. The apparatus of claim 1, wherein each of the plurality of row address capture logic circuits is configured to mask one or more bits of the captured address responsive to the refresh signal.

8. The apparatus of claim 1, further comprising a plurality of row decoders, each configured to refresh one or more word lines associated with the captured address in the associated one of the plurality of row address capture logic circuits responsive to the activation signal and the refresh signal.

9. An apparatus comprising:
a first memory bank;
a second memory bank;
a command decoder configured to receive a linked activation command and provide an activation signal and an inactive refresh signal to the first memory bank and an activation signal and an active refresh signal to the second memory bank;
an address decoder configured to receive a row address associated with the linked activation command and provide the row address as a first row address with an inactive refresh address flag along a row address bus;
a refresh address generator configured to generate a refresh address and provide the refresh address as a second row address with an active refresh address flag along the row address bus,
wherein the first memory bank is configured to latch the first row address responsive to receiving the inactive refresh signal and the first row address having the inactive refresh address flag, and wherein the second memory bank is configured to latch the second row address responsive to receiving the active refresh signal and the second row address having the active refresh flag.

10. The apparatus of claim 9, wherein the first bank doesn’t latch the second row address and the second bank doesn’t latch the first row address.

11. The apparatus of claim 9, wherein the refresh address flag is a bit of the first row address and a bit of the second row address, and wherein the bit of the first row address has an opposite state to the bit of the second row address.

12. The apparatus of claim 9, wherein the first memory bank and the second memory bank are in a bank logic region of the memory, and wherein the command decoder, the address decoder, and the refresh address generator are in a peripheral region.

13. The apparatus of claim 9, further comprising:
a first row address capture logic circuit associated with the first memory bank; and
a second row address capture logic circuit associated with the second memory bank,
wherein the first and the second row address capture logic circuits are configured to capture an address on the row address bus when a state of the refresh signal received by the associated bank matches a state of the refresh address flag of the address on the row address bus.

14. The apparatus of claim 9, wherein the second memory bank is configured to refresh one or more word lines associated with the second row address.

15. A method comprising:
receiving a linked activation command for a first bank along with a row address;
providing the row address as a first row address along a row address bus with an inactive refresh address flag;
generating a refresh address with a refresh address generator and providing the refresh address as a second row address along the row address bus with an active refresh address flag;
latching the first row address with a first bank; and
latching the second row address with a second bank.

16. The method of claim 15, further comprising:
accessing a word line in the first bank based on the first row address; and
refreshing one or more word lines in the second bank based on the second row address.

17. The method of claim 15, further comprising:
providing an inactive refresh signal to the first bank; and
providing an active refresh signal to the second bank.

18. The method of claim 17, further comprising:
latching the first row address with the first bank responsive to the inactive refresh signal and the inactive refresh address flag; and
latching the second row address with the second bank responsive to the active refresh signal and the active refresh address flag.

19. The method of claim 15, further comprising appending one or more refresh flag bits to the row address to generate the first row address.

20. The method of claim 15, further comprising masking one or more bits of the second row address and refreshing multiple word lines which share the unmasked portion in common.
